(19) United States
(12) Patent Application Publication
(10) Pub. No.: US 2025/0338461 A1
(43) Pub. Date: Oct. 30, 2025

(54) CONTROL METHOD, CONTROL APPARATUS, CONTROL SYSTEM, AND READABLE STORAGE MEDIUM

(71) Applicant: SHENZHEN HELLO TECH ENERGY CO., LTD, Shenzhen (CN)

(72) Inventors: Hongliang ZHAO, Shenzhen (CN); Gaosong SHEN, Shenzhen (CN); Feiyan LUO, Shenzhen (CN); Wenhai LIN, Shenzhen (CN); Qingbin LIN, Shenzhen (CN); Yang WU, Shenzhen (CN)

(21) Appl. No.: 19/264,881

(22) Filed: Jul. 10, 2025

Related U.S. Application Data
(63) Continuation of application No. PCT/CN2025/072089, filed on Jan. 13, 2025.

(30) Foreign Application Priority Data
Jun. 28, 2024 (CN) 202410868804.7

(51) Int. Cl. H05K 7/20

(52) U.S. Cl. CPC H05K 7/20945; H05K 7/20909

(57) ABSTRACT

A control method, a control apparatus, a control system, and a readable storage medium are provided. The control method for controlling a fan for a power conversion circuit board includes: determining a core cooling rotational speed based on a core temperature of the power conversion circuit board; determining a plurality of power cooling rotational speeds based on a heat radiation temperature of the power conversion circuit board and charging and discharging power of an energy storage system to which the power conversion circuit board is applied; and controlling the fan to rotate at a maximum rotational speed among the core cooling rotational speed and the plurality of power cooling rotational speeds.

### CROSS-REFERENCE TO RELATED APPLICATIONS

This application is a continuation of International Application No. PCT/CN2025/072089, filed on Jan. 13, 2025, which claims priority and interest to Chinese Patent Application No. 202410868804.7, filed with China National Intellectual Property Administration on Jun. 28, 2024, which are incorporated herein by reference in their entireties.

### FIELD

The present disclosure relates to the technical field of inverters, and in particular, to a control method, a control apparatus, a control system, and a readable storage medium.

### BACKGROUND

With the development of new energy technologies, input power of an inverter is increasing steadily, leading to a growing demand for heat dissipation and an increasing number of cooling fans. In addition, functions of the inverter are increasingly complex, with a greater variety of operation modes having varied heat-dissipation requirements. However, in the related technology, when the inverter operates in different operation modes, the cooling fan operates at a fixed maximum rotational speed to avoid a poor heat-dissipation effect, resulting in high energy consumption and large noise.

### SUMMARY

A control method, a control apparatus, a control system, and a readable storage medium are provided according to embodiments of the present disclosure.

The control method for controlling a fan for a power conversion circuit board according to an embodiment of the present disclosure includes: determining a core cooling rotational speed based on a core temperature of the power conversion circuit board; determining a plurality of power cooling rotational speeds based on a heat radiation temperature of the power conversion circuit board and charging and discharging power of an energy storage system to which the power conversion circuit board is applied; and controlling the fan to rotate at a maximum rotational speed among the core cooling rotational speed and the plurality of power cooling rotational speeds.

The control method according to the embodiment of the present disclosure determines the rotational speed of the fan based on the core temperature, the charging and discharging power, and the heat radiation temperature. While ensuring a heat-dissipation effect, the rotational speed of the fan may be adjusted automatically based on the heat-dissipation requirement, which effectively reduces energy consumption caused by the fan and is beneficial to reducing the use cost. Meanwhile, when the heat-dissipation requirement is low, the rotational speed of the fan is reduced, which is beneficial to reducing the noise generated when the fan rotates at a high speed.

In an embodiment, the core temperature is a maximum temperature of a core component of the power conversion circuit board, and the core component includes an inverter circuit, a buck-boost circuit, and/or a maximum power point tracking (MPPT) circuit.

Radiators of the inverter circuit, the buck-boost circuit, and the MPPT circuit are the core components that generate relatively high temperatures when the power conversion circuit board is in operation. Taking these radiators as a benchmark can effectively ensure that cooling requirements of most of electrical components within the power conversion circuit board are satisfied.

In an embodiment, the determining the core cooling rotational speed based on the core temperature of the power conversion circuit board includes: determining the core cooling rotational speed to be 0, in response to the core temperature being smaller than a rotation startup temperature; determining the core cooling rotational speed to gradually increase from a predetermined rotational speed of the fan to a maximum rotational speed of the fan as the core temperature rises, in response to the core temperature being greater than or equal to the rotation startup temperature and smaller than an overheating temperature; and determining the core cooling rotational speed to be the maximum rotational speed of the fan, in response to the core temperature being greater than or equal to the overheating temperature.

In this way, determining the rotational speed of the fan based on the core temperature is beneficial to energy conservation and noise reduction. In addition, when the core temperature is lower than the rotation startup temperature, the power conversion circuit board may dissipate heat by itself. At this time, there is no need to turn on the fan, which is beneficial to the energy conservation and noise reduction. When the core temperature is greater than or equal to the overheating temperature, the power conversion circuit board is overheated, and the fan needs to rotate at the highest speed to dissipate its heat as quickly as possible, to prevent the power conversion circuit board from being burned out.

In an embodiment, an increase rate of the core cooling rotational speed gradually increases as the core temperature rises.

As the core temperature rises, the heat-dissipation effect of the fan declines. Therefore, it is necessary to increase the increase rate of the core cooling rotational speed.

In an embodiment, the determining the plurality of power cooling rotational speeds based on the heat radiation temperature and the charging and discharging power of the energy storage system to which the power conversion circuit board is applied includes: determining a rotational speed upper-limit coefficient based on the heat radiation temperature; and determining the plurality of power cooling rotational speeds based on the rotational speed upper-limit coefficient and the charging and discharging power.

In this way, the rotational speed upper-limit coefficient and the charging and discharging power are utilized to determine the power cooling rotational speed, which is beneficial to making the power cooling rotational speed more accurate.

In an embodiment, the determining the rotational speed upper-limit coefficient based on the heat radiation temperature includes: determining the rotational speed upper-limit coefficient to be a first predetermined value, in response to the heat radiation temperature being smaller than a first predetermined temperature; determining the rotational speed upper-limit coefficient to gradually increase from the first predetermined value to 1 as the heat radiation temperature rises, in response to the heat radiation temperature being greater than or equal to the first predetermined temperature and smaller than a second predetermined temperature; and determining the rotational speed upper-limit coefficient to be 1, in response to the heat radiation temperature being greater than or equal to the second predetermined temperature.

Determining the rotational speed of the fan based on the heat radiation temperature is beneficial to the energy conservation and noise reduction. In addition, when the heat radiation temperature is lower than the rotation startup temperature, the heat-dissipation requirement of the power conversion circuit board can be satisfied by itself. At this time, there is no need to turn on the fan, which is beneficial to energy conservation and noise reduction.

In an embodiment, the first predetermined temperature is a heat radiation temperature when a rotational speed of the fan is a predetermined rotational speed and power of the power conversion circuit board reaches rated power; and/or the second predetermined temperature is a heat radiation temperature when the rotational speed of the fan is the maximum rotational speed and the power of the power conversion circuit board reaches the rated power.

In this way, it is beneficial to further precise control of the rotational speed of the fan.

In an embodiment, an increase rate of the rotational speed upper-limit coefficient gradually increases as the heat radiation temperature rises.

As the heat radiation temperature rises, the heat-dissipation effect of the fan declines. Therefore, it is necessary to increase the increase rate of the core cooling rotational speed.

In an embodiment, the determining the plurality of power cooling rotational speeds based on the rotational speed upper-limit coefficient and the charging and discharging power includes: obtaining an output current and a rated output current of the power conversion circuit board; and calculating a first power cooling rotational speed based on the output current, the rated output current, and the rotational speed upper-limit coefficient.

In this way, the first power cooling rotational speed required for a heat-dissipation requirement for the output current of the power conversion circuit board is determined.

In an embodiment, the determining the plurality of power cooling rotational speeds based on the rotational speed upper-limit coefficient and the charging and discharging power includes: obtaining a utility power charging current and a maximum utility power charging current of an energy storage device; and calculating a second power cooling rotational speed based on the utility power charging current, the maximum utility power charging current, and the rotational speed upper-limit coefficient.

In this way, the second power cooling rotational speed required for a heat-dissipation requirement for the utility power charging current is determined.

In an embodiment, the determining the plurality of power cooling rotational speeds based on the rotational speed upper-limit coefficient and the charging and discharging power includes: obtaining a utility power input current and a maximum input current limit value of the power conversion circuit board; and calculating a third power cooling rotational speed based on the utility power input current, the maximum input current limit value, and the rotational speed upper-limit coefficient.

In this way, the third power cooling rotational speed required for a heat-dissipation requirement for the utility power input current is determined.

In an embodiment, the determining the plurality of power cooling rotational speeds based on the rotational speed upper-limit coefficient and the charging and discharging power includes: obtaining a PV charging current and a maximum PV charging current of the power conversion circuit board; and calculating a fourth power cooling rotational speed based on the PV charging current, the maximum PV charging current, and the rotational speed upper-limit coefficient.

In this way, the fourth power cooling rotational speed required for a heat-dissipation requirement for the PV charging current is determined.

In an embodiment, the controlling the fan to rotate at the maximum rotational speed among the core cooling rotational speed and the plurality of power cooling rotational speeds includes: controlling the fan to rotate at a maximum rotational speed among the core cooling rotational speed, the first power cooling rotational speed, and the fourth power cooling rotational speed during charging of the energy storage system; and controlling the fan to rotate at a maximum rotational speed among the core cooling rotational speed, the second power cooling rotational speed, the third power cooling rotational speed, and the fourth power cooling rotational speed during discharging of the energy storage system.

In this way, the operation state is divided into a charging state and a discharging state, which is beneficial to more rapid and precise determination of the rotational speed of the fan.

A control apparatus for controlling a fan for a power conversion circuit board according to a second embodiment of the present disclosure includes: a first calculation module configured to determine a core cooling rotational speed based on a core temperature of the power conversion circuit board; a second calculation module configured to determine a plurality of power cooling rotational speeds based on a heat radiation temperature of the power conversion circuit board and charging and discharging power of an energy storage system to which the power conversion circuit board is applied; and a control module configured to control the fan to rotate at a maximum rotational speed among the core cooling rotational speed and the plurality of power cooling rotational speeds.

A control system according to a third embodiment of the present disclosure includes a processor and a memory. The memory stores a computer program. The computer program, when executed by the processor, causes the processor to implement an instruction of the control method as described in any one of the foregoing embodiments.

A non-transitory computer-readable storage medium is provided according to a fourth embodiment of the present disclosure. The computer-readable storage medium stores a computer program. The computer program, when executed by a processor, implements the control method as described in any one of the foregoing.

Additional aspects and advantages of embodiments of the present disclosure will be provided in part in the following description, or will become apparent in part from the following description, or can be learned from practicing of the embodiments of the present disclosure.

### BRIEF DESCRIPTION OF THE DRAWINGS

The above and/or additional aspects and advantages of the present disclosure will become more apparent and more understandable from the following description of embodiments taken in conjunction with the accompanying drawings.

FIG. 1 is a schematic flowchart of a control method for a control system according to an embodiment of the present disclosure.

FIG. 2 is a schematic diagram illustrating modules of a control apparatus for a control system according to an embodiment of the present disclosure.

FIG. 3 is a schematic diagram illustrating modules of a control system according to an embodiment of the present disclosure.

FIG. 4 is a schematic flowchart of a control method for a control system according to an embodiment of the present disclosure.

FIG. 5 is a schematic flowchart of a control method for a control system according to an embodiment of the present disclosure.

FIG. 6 is a schematic flowchart of a control method for a control system according to an embodiment of the present disclosure.

FIG. 7 is a schematic flowchart of a control method for a control system according to an embodiment of the present disclosure.

FIG. 8 is a schematic flowchart of a control method for a control system according to an embodiment of the present disclosure.

FIG. 9 is a schematic flowchart of a control method for a control system according to an embodiment of the present disclosure.

FIG. 10 is a schematic flowchart of a control method for a control system according to an embodiment of the present disclosure.

FIG. 11 is a schematic flowchart of a control method for a control system according to an embodiment of the present disclosure.

Reference Signs of main components: control system 100, control apparatus 10, first calculation module 11, second calculation module 12, control module 13, processor 20, memory 30.

### DETAILED DESCRIPTION

Embodiments of the present disclosure will be further described below with reference to the accompanying drawings, throughout which the same or similar elements, or the elements having same or similar functions, are denoted with same or similar reference numerals.

In addition, the embodiments of the present disclosure described below with reference to the accompanying drawings are illustrative and are only intended to explain the embodiments of the present disclosure, rather than limiting the present disclosure.

In the present disclosure, unless expressly stipulated and defined otherwise, the first feature “on” or “under” the second feature may mean that the first feature is in direct contact with the second feature, or the first and second features are in indirect contact through an intermediate. Moreover, the first feature “above” the second feature may mean that the first feature is directly above or obliquely above the second feature, or simply mean that the level of the first feature is higher than that of the second feature. The first feature “below” the second feature may mean that the first feature is directly below or obliquely below the second feature, or simply mean that the level of the first feature is smaller than that of the second feature.

With the development of new energy technologies, input power of inverters is increasing steadily, leading to a growing demand for heat dissipation, and an increasing number of cooling fans. In addition, functions of the inverter are becoming increasingly complex, with a greater variety of operation modes having varied heat-dissipation requirements. However, in the related technology, when the inverter operates in different operation modes, the cooling fan operates at a fixed maximum rotational speed to avoid a poor heat-dissipation effect, resulting in high energy consumption and large noise.

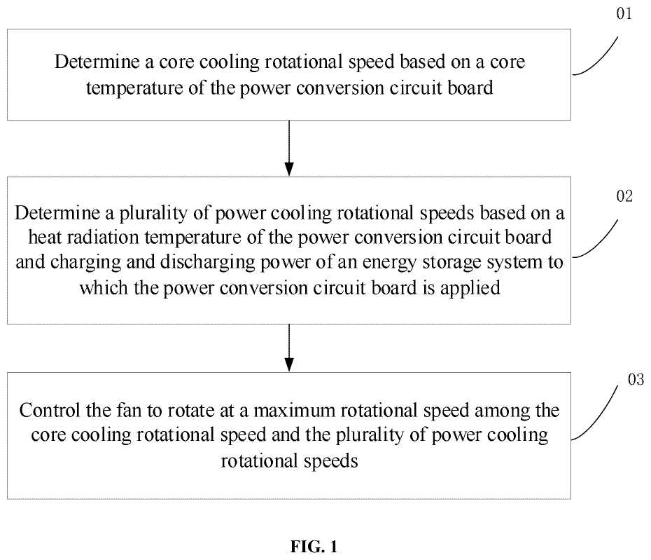

Referring to FIG. 1, a control method for controlling a fan for a power conversion circuit board according to an embodiment of the present disclosure includes the following steps 01 to 03.

At step 01, a core cooling rotational speed is determined based on a core temperature of the power conversion circuit board.

At step 02, a plurality of power cooling rotational speeds are determined based on a heat radiation temperature of the power conversion circuit board and charging and discharging power of an energy storage system to which the power conversion circuit board is applied.

At step 03, the fan is controlled to rotate at a maximum rotational speed among the core cooling rotational speed and the plurality of power cooling rotational speeds.

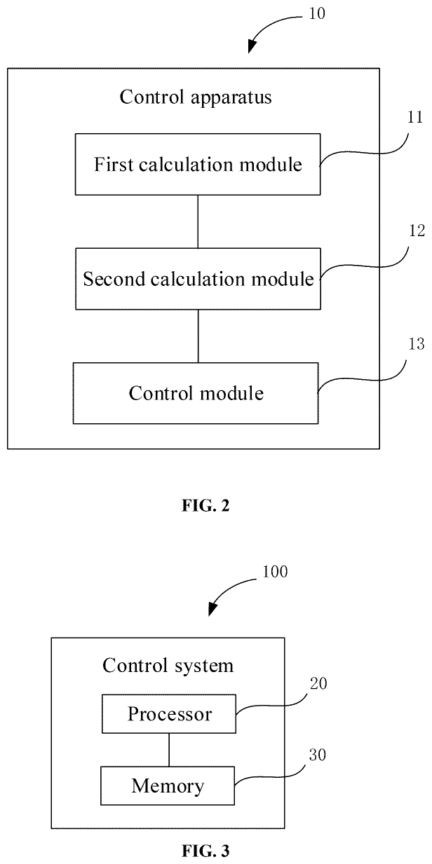

Referring to FIG. 2, a control apparatus 10 for controlling a fan for a power conversion circuit board is further provided according to an embodiment of the present disclosure. The control apparatus 10 includes a first calculation module 11, a second calculation module 12, and a control module 13. The first calculation module 11 is configured to determine a core cooling rotational speed based on a core temperature of the power conversion circuit board. The second calculation module 12 is configured to determine a plurality of power cooling rotational speeds based on a heat radiation temperature of the power conversion circuit board and charging and discharging power of an energy storage system to which the power conversion circuit board is applied. The control module 13 is configured to control the fan to rotate at a maximum rotational speed among the core cooling rotational speed and the plurality of power cooling rotational speeds.

Referring to FIG. 3, a control system 100 is further provided according to an embodiment of the present disclosure. The control system 100 includes a processor 20 and a memory 30. The memory 30 stores a computer program. The computer program, when executed by the processor 20, causes the processor 20 to implement an instruction of the control method of any of the foregoing. In other words, the processor 20 may be configured to determine a core cooling rotational speed based on a core temperature of the power conversion circuit board, determine a plurality of power cooling rotational speeds based on a heat radiation temperature of the power conversion circuit board and charging and discharging power of an energy storage system to which the power conversion circuit board is applied, and control the fan to rotate at a maximum rotational speed among the core cooling rotational speed and the plurality of power cooling rotational speeds.

The control method according to the embodiment of the present disclosure determines the rotational speed of the fan based on the core temperature, the charging and discharging power, and the heat radiation temperature. While ensuring the heat-dissipation effect, the rotational speed of the fan can be adjusted correspondingly based on the heat-dissipation requirement, which effectively reduces energy consumption caused by the fan, and is beneficial to reducing the use cost. Meanwhile, when the heat-dissipation requirement is relatively low, the fan speed will be reduced, which is beneficial to reducing the noise generated by the fan when rotating at a high speed.

In an embodiment, the power conversion circuit board includes an inverter circuit board (DC-AC) and an MPPT circuit board (DC-DC).

The core cooling rotational speed refers to a fan rotational speed for satisfying a heat-dissipation requirement of a core component of the power conversion circuit board.

The heat radiation temperature refers to a temperature around the power conversion circuit board due to heat emitted by the power conversion circuit board.

The charging and discharging power refers to input and output power of the power conversion circuit board and the energy storage system. Since the voltage is maintained constant during the input and output processes, the charging and discharging power is typically represented by the current during the input and output processes.

The power cooling rotational speed refers to a fan rotational speed satisfying a heat-dissipation requirement for heat generated by the power conversion circuit board under current charging and discharging power.

In an embodiment of the present disclosure, the fan is controlled to rotate at the maximum rotational speed among the core cooling rotational speed and the plurality of power cooling rotational speeds, to ensure that all cooling requirements of the power conversion circuit board are satisfied.

A duty cycle determines the rotational speed of the fan. In an embodiment, when the duty cycle is 100%, the fan operates continuously and reaches its maximum rotational speed; and when the duty cycle is 0%, the fan stops operating and has a rotational speed of zero. Therefore, in an embodiment of the present disclosure, descriptions related to the core cooling rotational speed and the plurality of power cooling rotational speeds are replaced with the duty cycle. In other words, the duty cycle is utilized to represent the core cooling rotational speed and the plurality of power cooling rotational speeds.

In an embodiment, the core temperature is a maximum temperature of a core component of the power conversion circuit board, and the core component includes an inverter circuit, a buck-boost circuit, and/or an MPPT circuit.

In this way, the inverter circuit, the buck-boost circuit, and the MPPT circuit are the core components that generate higher temperatures when the power conversion circuit board is in operation. Based on these components, it can be effectively ensured that cooling requirements of most of electrical components within the power conversion circuit board are satisfied.

Further, the inverter circuit, the buck-boost circuit, and the MPPT circuit each contain a MOS transistor. The MOS transistor generates the most heat in each of the inverter circuit, the buck-boost circuit, and the MPPT circuit, and a radiator is provided at the MOS transistor. Therefore, a maximum temperature of radiators of the inverter circuit, the buck-boost circuit, and the MPPT circuit may be determined as the core temperature.

In an embodiment, the inverter circuit is a common power electronic converter and serves as a core component of the power conversion circuit board. The inverter circuit is mainly used for converting a direct current power supply into an alternating current power supply. The inverter circuit includes four switching tubes (such as IGBTs, MOSFETs, and the like). By controlling these switching tubes to be turned on or off, a voltage of the direct current power supply, such as a battery or a power supply, is converted into a high-frequency and high-voltage alternating current power supply for use by devices like an alternating current electromotor and a frequency converter.

The buck-boost circuit refers to an electronic circuit that can achieve both buck and boost functions, making it a more flexible type of circuit. The buck-boost circuit is similar to a combination of a boost circuit and a buck circuit, and usually includes a switching tube, an inductor, and an output capacitor. The buck-boost circuit may be applied in various scenarios, such as a power adapter, an automotive ignition system, an electric vehicle charger, and a solar photovoltaic power generation system.

The MPPT circuit, namely a maximum power point tracking circuit, is a crucial technical circuit in the solar photovoltaic power generation system. The MPPT circuit is capable of monitoring and adjusting an operation point of a solar panel in real time, enabling the solar panel to always operate at a maximum power point (MPP). The MPPT circuit maximally extracts solar energy by adjusting an output voltage and current of the solar panel, thus improving efficiency of the entire solar photovoltaic power generation system.

The power conversion circuit board generates power losses during its operation, and most of the lost energy is released in the form of heat. As key components of the power conversion circuit board, the inverter circuit, the buck-boost circuit, and the MPPT circuit undertake main power conversion tasks, and have relatively high power losses and generate more heat. Moreover, due to operation characteristics and material properties of the inverter circuit, the buck-boost circuit, and the MPPT circuit, these components are generally more sensitive to temperature. In a high-temperature environment, failure rates of these components will increase, and their performance and service lives will also be affected.

In the embodiments of the present disclosure, the core components include, but are not limited to, the inverter circuit, the buck-boost circuit, and/or the MPPT circuit.

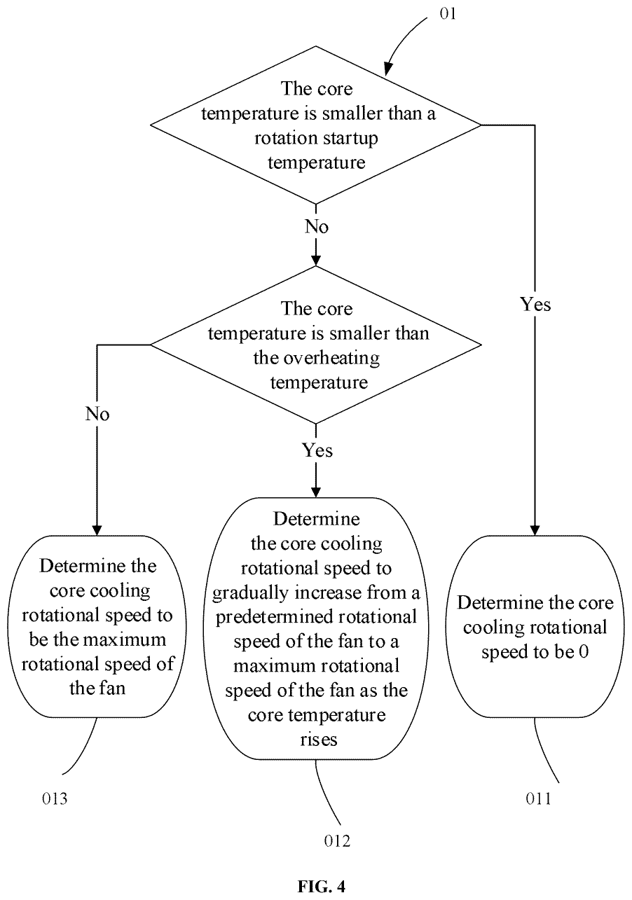

Referring to FIG. 4, in an embodiment, step 01 includes following sub-steps 011 to 013.

At sub-step 011, the core cooling rotational speed is determined to be 0, in response to the core temperature being smaller than a rotation startup temperature.

At sub-step 012, the core cooling rotational speed is determined to gradually increase from a predetermined rotational speed of the fan to a maximum rotational speed of the fan as the core temperature rises, in response to the core temperature being greater than or equal to the rotation startup temperature and smaller than an overheating temperature.

At sub-step 013, the core cooling rotational speed is determined to be the maximum rotational speed of the fan, in response to the core temperature being greater than or equal to the overheating temperature.

In this way, determining the rotational speed of the fan based on the core temperature is beneficial to energy conservation and noise reduction. In addition, when the core temperature is lower than the rotation startup temperature, the power conversion circuit board may dissipate heat by itself. At this time, there is no need to turn on the fan, which is beneficial to the energy conservation and noise reduction. When the core temperature is greater than or equal to the overheating temperature, the power conversion circuit board is overheated, and the fan needs to rotate at the highest speed to dissipate its heat as quickly as possible, to prevent the power conversion circuit board from being burned out.

In an embodiment, the sub-steps 011, 012, and 013 are implemented by the first calculation module 11, or the first calculation module 11 may be configured to: determine the core cooling rotational speed to be 0, in response to the core temperature being smaller than a rotation startup temperature; determine the core cooling rotational speed to gradually increase from a predetermined rotational speed of the fan to a maximum rotational speed of the fan as the core temperature rises, in response to the core temperature being greater than or equal to the rotation startup temperature and smaller than an overheating temperature; and determine the core cooling rotational speed to be the maximum rotational speed of the fan, in response to the core temperature being greater than or equal to the overheating temperature.

In an embodiment, the processor 20 may be configured to: determine the core cooling rotational speed to be 0, in response to the core temperature being smaller than a rotation startup temperature; determine the core cooling rotational speed to gradually increase from a predetermined rotational speed of the fan to a maximum rotational speed of the fan as the core temperature rises, in response to the core temperature being greater than or equal to the rotation startup temperature and smaller than an overheating temperature; and determine the core cooling rotational speed to be the maximum rotational speed of the fan, in response to the core temperature being greater than or equal to the overheating temperature.

In an embodiment, the rotation startup temperature refers to a minimum core temperature at which the heat-dissipation requirement of the power conversion circuit board cannot be satisfied through its own heat dissipation, and the fan needs to start to assist in heat dissipation of the power conversion circuit board.

The predetermined rotational speed is a minimum rotational speed at which the fan operates to assist the power conversion circuit board in dissipating heat to satisfy the heat-dissipation requirement of the power conversion circuit board when the core temperature reaches the rotation startup temperature.

The maximum rotational speed refers to a maximum rotational speed that the fan can reach under specific conditions. The maximum rotational speed of the fan may vary depending on device design, operation conditions, or manufacturing requirements.

The overheating temperature refers to an upper limit temperature at which an internal temperature of the power conversion circuit board exceeds its normal operation range during its operation, caused by heat generated from power losses or other reasons. This temperature limit is set to ensure performance and reliability of the power conversion circuit board. Once this temperature limit is exceeded, the power conversion circuit board may be automatically shut down or suffer irreparable damage. Therefore, in order to ensure that the power conversion circuit board can dissipate heat as quickly as possible and reduce a probability of damage, the core cooling rotational speed should be maintained at the maximum rotational speed.

In an embodiment of the present disclosure, when the core temperature is greater than or equal to the rotation startup temperature and smaller than the overheating temperature, since the power conversion circuit board adopts forced convection, heat dissipated per unit time may be calculated by the following equation:

$$Q = H \times S \times Δ t ,$$

where Q is heat to be dissipated, His a forced convection heat transfer coefficient, S is a heat-dissipation area, and Δt is a unit time.

A relationship between the Nusselt number, the Reynolds number, and the Prandtl number is expressed by the Dittus-Boelter equation:

$$N u = C \times {Re}^{m} \times P {r}^{n} ,$$

where Nu is the Nusselt number, Re is the Reynolds number, Pr is the Prandtl number, and C, m, and n are constants with 0<m and n<1.

Since Re=VL/v and H=k/L×Nu, the following equation may be obtained by substituting them into the above equation:

$$H = {V}^{m} ( k C {L}^{m - 1} {v}^{- m} P {r}^{n} ) ,$$

where k is thermal conductivity of the fluid, L is a characteristic length, and v is dynamic viscosity.

Since the parameters k, L, and v within the brackets remain unchanged for one power conversion circuit board, minor differences between the parameters caused by changes in a wind speed can be neglected, and both C and the Prandtl number are constants. Therefore, kCL^{m-1}v^{-m}Prⁿ can be regarded as a constant. Given that K=kCL^{m-1}v^{-m}Prⁿ,

$$H = K {V}^{m} ,$$

where V^{m} is a power function, and H increases as V increases.

$$Since Q = H \times S \times Δ t , i . e .$$

$$Q = K \times S \times Δ t \times {V}^{m} ,$$

it can be known that when the heat-dissipation area and the unit time remain unchanged, a larger value of Q requires a larger value of V. Moreover, the value of Q is determined by the core temperature, and the flow velocity V passing through the power conversion circuit board is determined by the core cooling rotational speed of the fan. Therefore, the core cooling rotational speed gradually increases from the predetermined rotational speed of the fan to the maximum rotational speed of the fan as the core temperature rises.

In an embodiment, an increase rate of the core cooling rotational speed gradually increases as the core temperature rises.

As the core temperature rises, the heat-dissipation effect of the fan declines. Therefore, it is necessary to increase the increase rate of the core cooling rotational speed.

In an embodiment, since Q=K×S×Δt×V^{m} is a power function and 0<m<1, the increase rate of the core cooling rotational speed gradually increases as the core temperature rises.

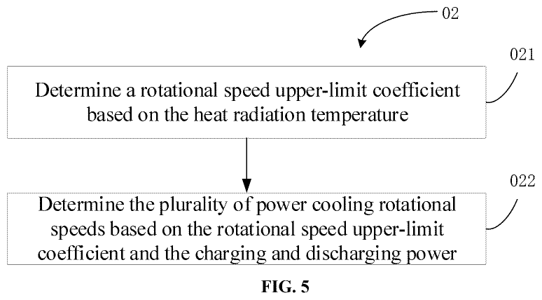

Referring to FIG. 5, in an embodiment, step 02 includes following sub-steps 021 and 022.

At sub-step 021, a rotational speed upper-limit coefficient is determined based on the heat radiation temperature.

At sub-step 022, the plurality of power cooling rotational speeds are determined based on the rotational speed upper-limit coefficient and the charging and discharging power.

In this way, the power cooling rotational speed is determined by using the rotational speed upper-limit coefficient and the charging and discharging power, which increases the accuracy of the power cooling rotational speed.

In an embodiment, the sub-steps 021 and 022 are implemented by the second calculation module 12, or the second calculation module 12 may be configured to determine a rotational speed upper-limit coefficient based on the heat radiation temperature and determine the plurality of power cooling rotational speeds based on the rotational speed upper-limit coefficient and the charging and discharging power.

In an embodiment, the processor 20 may be configured to determine a rotational speed upper-limit coefficient based on the heat radiation temperature and determine the plurality of power cooling rotational speeds based on the rotational speed upper-limit coefficient and the charging and discharging power.

In an embodiment, the rotational speed upper-limit coefficient is a rotational speed coefficient for load speed regulation generated based on the heat radiation temperature.

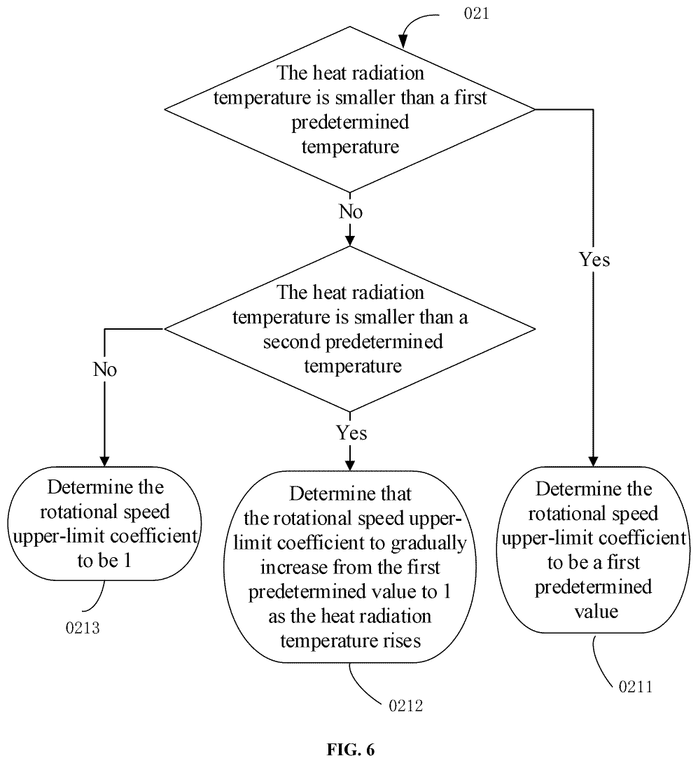

Referring to FIG. 6, in an embodiment, sub-step 021 includes following sub-steps 0211 to 0213.

At sub-step 0211, the rotational speed upper-limit coefficient is determined to be a first predetermined value, in response to the heat radiation temperature being smaller than a first predetermined temperature.

At sub-step 0212, the rotational speed upper-limit coefficient is determined to gradually increase from the first predetermined value to 1 as the heat radiation temperature rises, in response to the heat radiation temperature being greater than or equal to the first predetermined temperature and smaller than a second predetermined temperature.

At sub-step 0213, the rotational speed upper-limit coefficient is determined to be 1, in response to the heat radiation temperature being greater than or equal to the second predetermined temperature.

In this way, determining the rotational speed of the fan based on the heat radiation temperature is beneficial to energy conservation and noise reduction. In addition, when the heat radiation temperature is lower than the rotation startup temperature, heat-dissipation of the power conversion circuit board itself can satisfy the heat-dissipation requirement. At this time, there is no need to turn on the fan, which is beneficial to the energy conservation and noise reduction.

In an embodiment, the sub-steps 0211, 0212, and 0213 are implemented by the second calculation module 12, or the second calculation module 12 may be configured to: determine the rotational speed upper-limit coefficient to be a first predetermined value, in response to the heat radiation temperature being smaller than a first predetermined temperature; determine the rotational speed upper-limit coefficient to gradually increase from the first predetermined value to 1 as the heat radiation temperature rises, in response to the heat radiation temperature being greater than or equal to the first predetermined temperature and smaller than a second predetermined temperature; and determine the rotational speed upper-limit coefficient to be 1, in response to the heat radiation temperature being greater than or equal to the second predetermined temperature.

In an embodiment, the processor 20 may be configured to: determine the rotational speed upper-limit coefficient to be a first predetermined value, in response to the heat radiation temperature being smaller than a first predetermined temperature; determine the rotational speed upper-limit coefficient to gradually increase from the first predetermined value to 1 as the heat radiation temperature rises, in response to the heat radiation temperature being greater than or equal to the first predetermined temperature and smaller than a second predetermined temperature; and determine the rotational speed upper-limit coefficient to be 1, in response to the heat radiation temperature being greater than or equal to the second predetermined temperature.

In this embodiment, the rotational speed upper-limit coefficient Gₙ is a ratio of a rotational speed Nₙ that theoretically satisfies a heat-dissipation requirement of the power conversion circuit board at the heat radiation temperature to a maximum rotational speed Nₘₐₓ, i.e.,

$${G}_{n} = {N}_{n} / {N}_{max} .$$

The first predetermined value is a ratio of a rotational speed N₁ that theoretically satisfies a heat-dissipation requirement of the power conversion circuit board when the heat radiation temperature is the first predetermined temperature to the maximum rotational speed Nₘₐₓ, i.e., G₁=N₁/Nₘₐₓ.

The heat radiation temperature is determined by the core temperature. The core cooling rotational speed gradually increases from the predetermined rotational speed of the fan to the maximum rotational speed of the fan as the core temperature rises. Therefore, the rotational speed upper-limit coefficient gradually increases from the first predetermined value to the maximum value, i.e., Gₘₐₓ=Nₘₐₓ/Nₘₐₓ=1, as the heat radiation temperature rises.

In an embodiment, the first predetermined temperature is a heat radiation temperature when a rotational speed of the fan is a predetermined rotational speed and power of the power conversion circuit board reaches rated power; and/or the second predetermined temperature is a heat radiation temperature when the rotational speed of the fan is the maximum rotational speed and the power of the power conversion circuit board reaches the rated power.

In this way, the rotational speed of the fan can be controlled precisely.

In an embodiment, an ambient temperature around the power conversion circuit board is used as the heat radiation temperature, i.e., the ambient temperature around the power conversion circuit board when the core temperature is the rotation startup temperature is determined as the first predetermined temperature. The ambient temperature around the power conversion circuit board when the core temperature is the overheating temperature is determined as the second predetermined temperature.

In an embodiment, an increase rate of the rotational speed upper-limit coefficient gradually increases as the heat radiation temperature rises.

As the heat radiation temperature rises, the heat-dissipation effect of the fan declines. Therefore, it is necessary to increase the increase rate of the core cooling rotational speed.

In an embodiment, since the increase rate of the core cooling rotational speed gradually increases as the core temperature rises, the heat radiation temperature is determined by the core temperature, and Gₙ=Nₙ/Nₘₐₓ, the increase rate of the rotational speed upper-limit coefficient gradually increases as the heat radiation temperature rises.

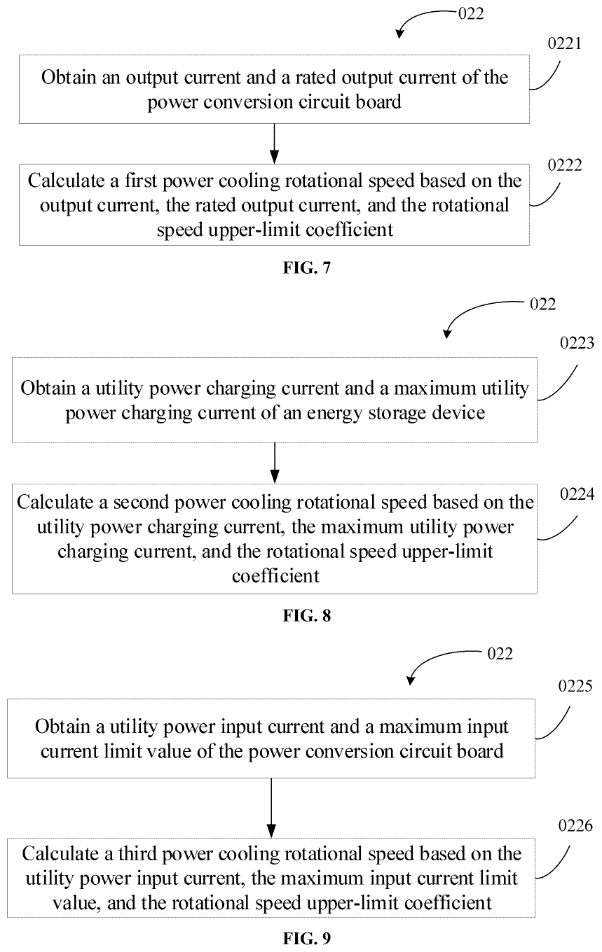

Referring to FIG. 7, in an embodiment, sub-step 022 includes following sub-steps 0221 and 0222.

At sub-step 0221, an output current and a rated output current of the power conversion circuit board are obtained.

At sub-step 0222, a first power cooling rotational speed is calculated based on the output current, the rated output current, and the rotational speed upper-limit coefficient.

In this way, the first power cooling rotational speed required for a heat-dissipation requirement for the output current of the power conversion circuit board is determined.

In an embodiment, the sub-steps 0221 and 0222 are implemented by the second calculation module 12, or the second calculation module 12 may be configured to: obtain an output current and a rated output current of the power conversion circuit board; and calculate a first power cooling rotational speed based on the output current, the rated output current, and the rotational speed upper-limit coefficient.

In an embodiment, the processor 20 may be configured to: obtain an output current and a rated output current of the power conversion circuit board; and calculate a first power cooling rotational speed based on the output current, the rated output current, and the rotational speed upper-limit coefficient.

In an embodiment of the present disclosure, the first power cooling rotational speed is: a minimum fan rotational speed satisfying a current heat-dissipation requirement only in a discharging mode based on a ratio of the output current to the rated current of the power conversion circuit board.

A relationship between the first power cooling rotational speed and the output current is determined by the following equation:

$$The first power cooling rotational speed = ( The output current / The rated output current ) \times G .$$

Referring to FIG. 8, in an embodiment, the sub-step 022 includes following sub-steps 0223 and 0224.

At sub-step 0223, a utility power charging current and a maximum utility power charging current of an energy storage device are obtained.

At sub-step 0224, a second power cooling rotational speed is calculated based on the utility power charging current, the maximum utility power charging current, and the rotational speed upper-limit coefficient.

In this way, the second power cooling rotational speed required for a heat-dissipation requirement for the utility power charging current is determined.

In an embodiment, the sub-steps 0223 and 0224 are implemented by the second calculation module 12, or the second calculation module 12 may be configured to: obtain a utility power charging current and a maximum utility power charging current of an energy storage device; and calculate a second power cooling rotational speed based on the utility power charging current, the maximum utility power charging current, and the rotational speed upper-limit coefficient.

In an embodiment, the processor 20 may be configured to: obtain a utility power charging current and a maximum utility power charging current of an energy storage device; and calculate a second power cooling rotational speed based on the utility power charging current, the maximum utility power charging current, and the rotational speed upper-limit coefficient.

In an embodiment of the present disclosure, since a current of the energy storage device will have a slight change during a charging process, specifically a gradual increase as a charging amount increases, the charging current at the energy storage device is used herein to calculate the rotational speed of the fan, to ensure accuracy of the calculation result.

Further, the second power cooling rotational speed is: a minimum fan rotational speed satisfying a current heat-dissipation requirement only in the charging mode based on the charging current at the energy storage device.

A relationship between the second power cooling rotational speed and the utility power charging current is determined by the following equation:

$$The second power cooling rotational speed = ( The charging current at the energy storage device / The maximum charging current at the energy storage device ) \times G .$$

Referring to FIG. 9, in an embodiment, sub-step 022 includes following sub-steps 0225 and 0226.

At sub-step 0225, a utility power input current and a maximum input current limit value of the power conversion circuit board are obtained.

At sub-step 0226, a third power cooling rotational speed is calculated based on the utility power input current, the maximum input current limit value, and the rotational speed upper-limit coefficient.

In this way, the third power cooling rotational speed required for a heat-dissipation requirement for the utility power input current is determined.

In an embodiment, the sub-steps 0225 and 0226 are implemented by the second calculation module 12, or the second calculation module 12 may be configured to: obtain a utility power input current and a maximum input current limit value of the power conversion circuit board; and calculate a third power cooling rotational speed based on the utility power input current, the maximum input current limit value, and the rotational speed upper-limit coefficient.

In an embodiment, the processor 20 may be configured to: obtain a utility power input current and a maximum input current limit value of the power conversion circuit board; and calculate a third power cooling rotational speed based on the utility power input current, the maximum input current limit value, and the rotational speed upper-limit coefficient.

In an embodiment, the third power cooling rotational speed is a minimum fan rotational speed satisfying a current heat-dissipation requirement based on a grid-side utility power input current when the energy storage system is charged by utility power.

A relationship between the third power cooling rotational speed and the utility power input current is determined by the following equation:

$$The third power cooling rotational speed = ( The utility power input current / The maximum input current limit value ) \times G .$$

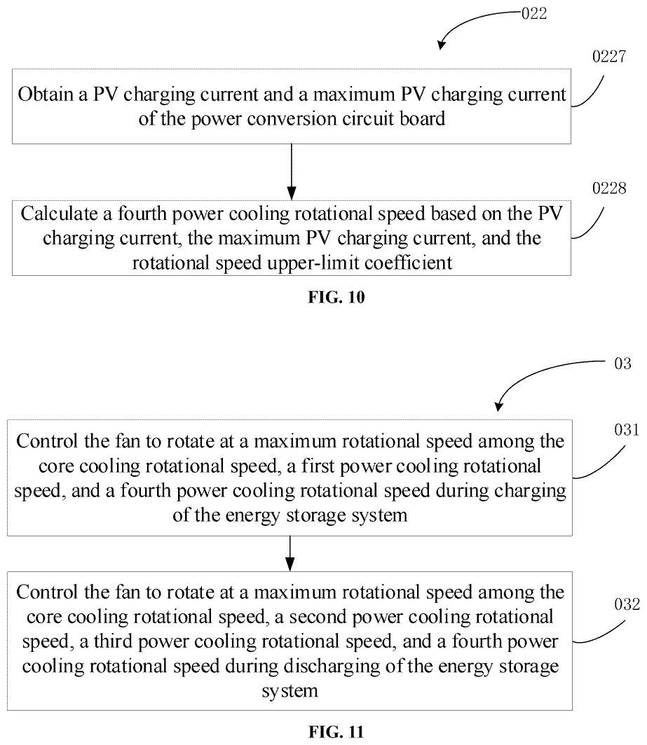

Referring to FIG. 10, in an embodiment, the sub-step 022 includes sub-steps 0227 and 0228.

At sub-step 0227, a PV charging current and a maximum PV charging current of the power conversion circuit board are obtained.

At sub-step 0228, a fourth power cooling rotational speed is calculated based on the PV charging current, the maximum PV charging current, and the rotational speed upper-limit coefficient.

In this way, the fourth power cooling rotational speed required for a heat-dissipation requirement for the PV charging current is determined.

In an embodiment, the sub-steps 0227 and 0228 are implemented by the second calculation module 12, or the second calculation module 12 may be configured to: obtain a PV charging current and a maximum PV charging current of the power conversion circuit board; and calculate a fourth power cooling rotational speed based on the PV charging current, the maximum PV charging current, and the rotational speed upper-limit coefficient.

In an embodiment, the processor 20 may be configured to: obtain a PV charging current and a maximum PV charging current of the power conversion circuit board; and calculate a fourth power cooling rotational speed based on the PV charging current, the maximum PV charging current, and the rotational speed upper-limit coefficient.

In an embodiment, the fourth power cooling rotational speed is: a minimum fan rotational speed satisfying a current heat-dissipation requirement based on the PV charging current value when the energy storage system is charged by solar power;

A relationship between the fourth power cooling rotational speed and the PVT charging current is determined by the following equation:

$$The fourth power cooling rotational speed = ( The PV charging current / The maximum PV charging current ) \times G .$$

Referring to FIG. 11, in an embodiment, step 03 includes sub-steps 031 and 032.

At sub-step 031, the fan is controlled to rotate at a maximum rotational speed among the core cooling rotational speed, the first power cooling rotational speed, and the fourth power cooling rotational speed, during charging of the energy storage system.

At sub-step 032, the fan is controlled to rotate at a maximum rotational speed among the core cooling rotational speed, the second power cooling rotational speed, the third power cooling rotational speed, and the fourth power cooling rotational speed, during discharging of the energy storage system.

In this way, the operation state is divided into a charging state and a discharging state, which is beneficial to more rapid and precise determination of the rotational speed of the fan.

In an embodiment, the sub-steps 031 and 032 are implemented by the control module 13, or the control module 13 may be configured to: control the fan to rotate at a maximum rotational speed among the core cooling rotational speed, the first power cooling rotational speed, and the fourth power cooling rotational speed, during charging of the energy storage system; or control the fan to rotate at a maximum rotational speed among the core cooling rotational speed, the second power cooling rotational speed, the third power cooling rotational speed, and the fourth power cooling rotational speed, during discharging of the energy storage system.

In an embodiment, the processor 20 may be configured to: control the fan to rotate at a maximum rotational speed among the core cooling rotational speed, the first power cooling rotational speed, and the fourth power cooling rotational speed, during charging of the energy storage system; or control the fan to rotate at a maximum rotational speed among the core cooling rotational speed, the second power cooling rotational speed, the third power cooling rotational speed, and the fourth power cooling rotational speed, during discharging of the energy storage system.

In an embodiment, the energy storage system may be charged by utility power in two cases, including a charging mode or a simultaneous charging and discharging mode. However, in the simultaneous charging and discharging mode, during discharging, the utility power may be directly introduced into a branch circuit without passing through the power conversion circuit board. Therefore, it is only necessary to consider the third power cooling rotational speed in the charging mode.

Similarly, the energy storage system may be charged by solar power in two cases, including a charging mode or a simultaneous charging and discharging mode. Since the power conversion circuit board needs to be used in both the two cases, the fourth power cooling speed needs to be considered in both the charging mode and the discharging mode.

Further, in an embodiment of the present disclosure, the fan should be controlled to rotate at a maximum rotational speed among the core cooling rotational speed, the first power cooling rotational speed, and the fourth power cooling rotational speed, during charging of the energy storage system; and the fan should be controlled to rotate at a maximum rotational speed among the core cooling rotational speed, the second power cooling rotational speed, the third power cooling rotational speed, and the fourth power cooling rotational speed, during discharging of the energy storage system.

A non-transitory computer-readable storage medium is provided according to an embodiment of the present disclosure. The non-transitory computer-readable storage medium stores a computer program. The computer program, when executed by the processor 20, implements the control method of any of the above embodiment.

In the above embodiments, these functions may be implemented fully or partially by software, hardware, firmware or any other combination. When implemented by software, it is possible to implement the functions fully or partially in a form of computer program products. The computer program product includes one or more computer instructions. When the computer program instructions are loaded and executed by the computer, procedures or functions according to embodiments of the present disclosure are fully or partially generated. The computer may be a general-purpose computer, a special-purpose computer, a computer network, or any other programmable device. The computer instructions may be stored in a computer-readable storage medium, or may be transmitted from one computer-readable storage medium to another computer-readable storage medium. For example, the computer instructions may be transmitted from one website, computer, server or data center to another website, computer, server or data center in a wired manner (for example, via coaxial cables, fiber optics, or digital subscriber lines (DSLs)) or in a wireless manner (for example, via infrared, wireless or microwave). The computer-readable storage medium may be any available medium that are accessible by the computer, or a data storage device such as a server or a data center integrated with one or more available medium. The available medium may be magnetic medium (for example, floppy disk, hard disk and tape), optical medium (for example, digital video disc (DVD)), or semiconductor medium (for example, solid state disk (SSD)).

In the description of this specification, descriptions with reference to the terms “certain embodiments”, “an embodiment”, “some embodiments”, “schematic embodiments”, “examples”, “specific examples”, or “some examples” etc., mean that specific features, structures, materials or characteristics described in conjunction with the embodiment or example are included in at least one embodiment or example of the present disclosure. In this specification, the schematic representations of the above terms do not necessarily refer to the same embodiment or example. Moreover, the described specific features, structures, materials or characteristics may be combined in any one or more embodiments or examples in a suitable manner.

In addition, the terms “first” and “second” are only used for descriptive purposes, and cannot be understood as indicating or implying relative importance or implicitly indicating the number of indicated technical features. Therefore, the features associated with “first” and “second” may explicitly or implicitly include at least one of the features. In the description of the present disclosure, “plurality of” means at least two, such as two, three, etc., unless otherwise specifically defined.

Although embodiments according to the present disclosure have been shown and described, it would be appreciated by those skilled in the art that the above embodiments are illustrative and cannot be construed to limitation on the present disclosure, and changes, alternatives, modifications, and variations can be made in the embodiments without departing from scope of the present disclosure.

What is claimed is:

1. A control method for controlling a fan for a power conversion circuit board, wherein the control method comprises:
determining a core cooling rotational speed based on a core temperature of the power conversion circuit board;
determining a plurality of power cooling rotational speeds based on a heat radiation temperature of the power conversion circuit board and charging and discharging power of an energy storage system to which the power conversion circuit board is applied; and
controlling the fan to rotate at a maximum rotational speed among the core cooling rotational speed and the plurality of power cooling rotational speeds.

2. The control method according to claim 1, wherein the core temperature is a maximum temperature of a core component of the power conversion circuit board, and the core component comprises an inverter circuit, a buck-boost circuit, and/or a maximum power point tracking (MPPT) circuit.

3. The control method according to claim 1, wherein said determining the core cooling rotational speed based on the core temperature of the power conversion circuit board comprises:
determining the core cooling rotational speed to be 0, in response to the core temperature being smaller than a rotation startup temperature;
determining the core cooling rotational speed to gradually increase from a predetermined rotational speed of the fan to a maximum rotational speed of the fan as the core temperature rises, in response to the core temperature being greater than or equal to the rotation startup temperature and smaller than an overheating temperature; and
determining the core cooling rotational speed to be the maximum rotational speed of the fan, in response to the core temperature being greater than or equal to the overheating temperature.

4. The control method according to claim 3, wherein an increase rate of the core cooling rotational speed gradually increases as the core temperature rises.

5. The control method according to claim 1, wherein said determining the plurality of power cooling rotational speeds based on the heat radiation temperature and the charging and discharging power of the energy storage system to which the power conversion circuit board is applied comprises:
determining a rotational speed upper-limit coefficient based on the heat radiation temperature; and
determining the plurality of power cooling rotational speeds based on the rotational speed upper-limit coefficient and the charging and discharging power.

6. The control method according to claim 5, wherein the rotational speed upper-limit coefficient is a ratio of a rotational speed satisfying a heat-dissipation requirement of the power conversion circuit board at the heat radiation temperature to the maximum rotational speed.

7. The control method according to claim 5, wherein said determining the rotational speed upper-limit coefficient based on the heat radiation temperature comprises:
determining the rotational speed upper-limit coefficient to be a first predetermined value, in response to the heat radiation temperature being smaller than a first predetermined temperature;
determining the rotational speed upper-limit coefficient to gradually increase from the first predetermined value to 1 as the heat radiation temperature rises, in response to the heat radiation temperature being greater than or equal to the first predetermined temperature and smaller than a second predetermined temperature; and
determining the rotational speed upper-limit coefficient to be 1, in response to the heat radiation temperature being greater than or equal to the second predetermined temperature.

8. The control method according to claim 7, wherein:
the first predetermined temperature is a heat radiation temperature when a rotational speed of the fan is a predetermined rotational speed and power of the power conversion circuit board reaches rated power; and/or
the second predetermined temperature is a heat radiation temperature when the rotational speed of the fan is the maximum rotational speed and the power of the power conversion circuit board reaches the rated power.

9. The control method according to claim 7, wherein an increase rate of the rotational speed upper-limit coefficient gradually increases as the heat radiation temperature rises.

10. The control method according to claim 5, wherein said determining the plurality of power cooling rotational speeds based on the rotational speed upper-limit coefficient and the charging and discharging power comprises:
obtaining an output current and a rated output current of the power conversion circuit board; and
calculating a first power cooling rotational speed based on the output current, the rated output current, and the rotational speed upper-limit coefficient.

11. The control method according to claim 10, wherein:
the first power cooling rotational speed is a minimum rotational speed of the fan satisfying a current heat-dissipation requirement in a discharging mode; and
the first power cooling rotational speed is determined by the following equation:
$$t he first power cooling rotational speed = ( the output current of the power conversion circuit board / the rated output current of the power conversion circuit board ) \times the rotational speed upper - limit coefficient .$$

12. The control method according to claim 5, wherein said determining the plurality of power cooling rotational speeds based on the rotational speed upper-limit coefficient and the charging and discharging power comprises:
obtaining a utility power charging current and a maximum utility power charging current of an energy storage device; and
calculating a second power cooling rotational speed based on the utility power charging current, the maximum utility power charging current, and the rotational speed upper-limit coefficient.

13. The control method according to claim 12, wherein:
the second power cooling rotational speed is a minimum fan rotational speed satisfying a current heat-dissipation requirement in a charging mode; and
the second power cooling rotational speed is determined by the following equation:
$$t he second power cooling rotational speed = ( a charging current at the energy storage device / a maximum charging current at the energy storage device ) \times the rotational speed upper - limit coefficient .$$

14. The control method according to claim 5, wherein said determining the plurality of power cooling rotational speeds based on the rotational speed upper-limit coefficient and the charging and discharging power comprises:
obtaining a utility power input current and a maximum input current limit value of the power conversion circuit board; and
calculating a third power cooling rotational speed based on the utility power input current, the maximum input current limit value, and the rotational speed upper-limit coefficient.

15. The control method according to claim 14, wherein:
the third power cooling rotational speed is a minimum fan rotational speed satisfying a current heat-dissipation requirement when the energy storage system is charged by utility power; and
the third power cooling rotational speed is determined by the following equation:
$$the third power cooling rotational speed = ( the utility power input current / the maximum input current limit value ) \times the rotational speed upper - limit coefficient .$$

16. The control method according to claim 5, wherein said determining the plurality of power cooling rotational speeds based on the rotational speed upper-limit coefficient and the charging and discharging power comprises:
obtaining a PV charging current and a maximum PV charging current of the power conversion circuit board; and
calculating a fourth power cooling rotational speed based on the PV charging current, the maximum PV charging current, and the rotational speed upper-limit coefficient.

17. The control method according to claim 16, wherein:
the fourth power cooling rotational speed is a minimum fan rotational speed satisfying a current heat-dissipation requirement when the energy storage system is charged by solar power; and
the fourth power cooling rotational speed is determined by the following equation:
$$the fourth power cooling rotational speed = ( the PV charging current / the maximum PV charging current ) \times the rotational speed upper - limit coefficient .$$

18. The control method according to claim 1, wherein said controlling the fan to rotate at the maximum rotational speed among the core cooling rotational speed and the plurality of power cooling rotational speeds comprises:
controlling the fan to rotate at a maximum rotational speed among the core cooling rotational speed, a first power cooling rotational speed, and a fourth power cooling rotational speed during charging of the energy storage system; and
controlling the fan to rotate at a maximum rotational speed among the core cooling rotational speed, a second power cooling rotational speed, a third power cooling rotational speed, and a fourth power cooling rotational speed during discharging of the energy storage system.

19. A control system, comprising:
a processor; and
a memory storing a computer program, wherein the computer program, when executed by the processor, causes the processor to implement a control method for controlling a fan for a power conversion circuit board, the control method comprising:
determining a core cooling rotational speed based on a core temperature of the power conversion circuit board;
determining a plurality of power cooling rotational speeds based on a heat radiation temperature of the power conversion circuit board and charging and discharging power of an energy storage system to which the power conversion circuit board is applied; and
controlling the fan to rotate at a maximum rotational speed among the core cooling rotational speed and the plurality of power cooling rotational speeds.

20. A non-transitory computer-readable storage medium, storing a computer program, wherein the computer program, when executed by a processor, implements a control method for controlling a fan for a power conversion circuit board, the control method comprising:
determining a core cooling rotational speed based on a core temperature of the power conversion circuit board;
determining a plurality of power cooling rotational speeds based on a heat radiation temperature of the power conversion circuit board and charging and discharging power of an energy storage system to which the power conversion circuit board is applied; and
controlling the fan to rotate at a maximum rotational speed among the core cooling rotational speed and the plurality of power cooling rotational speeds.
